(19) United States
(12) Patent Application Publication
(10) Pub. No.: US 2008/0094900 A1
(43) Pub. Date: Apr. 24, 2008

(54) NONVOLATILE SEMICONDUCTOR MEMORY

(76) Inventors: Dai NAKAMURA, Kawasaki-shi (JP); Koji Hosono, Fujisawa-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/874,458

(22) Filed: Oct. 18, 2007

(30) Foreign Application Priority Data
Oct. 20, 2006 (JP) 2006-286913

(51) Int. Cl. G11C 16/04

(52) U.S. Cl. 365/185.11

(57) ABSTRACT

A nonvolatile semiconductor memory according to an example of the present invention includes first and second word lines extending in a first direction and having the same row address, a first block including the first word line and having a first block address, a second block including the second word line and having a second block address, first and second signal lines extending in a second direction crossing the first direction, a first transfer transistor connected between the first word line and the first signal line, a second transfer transistor connected between the second word line and the second signal line, and a transfer voltage selector to output a transfer voltage to the first and second signal lines.

### CROSS-REFERENCE TO RELATED APPLICATIONS

This application is based upon and claims the benefit of priority from prior Japanese Patent Application No. 2006-286913, filed Oct. 20, 2006, the entire contents of which are incorporated herein by reference.

### BACKGROUND OF THE INVENTION

1. Field of the Invention

The present invention relates to a nonvolatile semiconductor memory, which is used for a NAND type flash memory, for example.

2. Description of the Related Art

Microfabrication of a memory cell is indispensable for increase of memory capacity of the nonvolatile semiconductor memory. For example, recently, the NAND type flash memory has been used as a main storage memory of light-weight, thin, short and small type electronic equipment, and microfabrication of the memory cell has been progressing for the increase of the memory capacity as the functions of electronic equipment are varied.

Although the memory cell size is shrunk on one hand, it is not possible to reduce the size of a transfer transistor in a word line driver to that of the memory cell because the size of the transfer transistor size is restricted by magnitude of a write voltage supplied to a word line at the time of write.

Consequently, at present, width in column direction of the transfer transistor is larger than width in column direction of a block (NAND string). As a result, a layout of conductive lines within the word line driver becomes complicated, so that it causes parasitic capacitance to increase (for example, refer to Jpn. Pat. Appln. KOKAI Publication Nos. 2002-141477 and 2005-39016).

### BRIEF SUMMARY OF THE INVENTION

A nonvolatile semiconductor memory according to an aspect of the present invention comprises first and second word lines extending in a first direction and having the same row address, a first block including the first word line and having a first block address, a second block including the second word line and having a second block address, first and second signal lines extending in a second direction crossing the first direction, a first transfer transistor connected between the first word line and the first signal line, a second transfer transistor connected between the second word line and the second signal line, and a transfer voltage selector to output a transfer voltage to the first and second signal lines.

### BRIEF DESCRIPTION OF THE SEVERAL VIEWS OF THE DRAWING

FIG. 1 is a view showing a NAND type flash memory;

FIG. 2 is a view showing a memory cell array and a word line driver;

FIG. 3 is a plan view showing a cell unit;

FIG. 4 is a cross sectional view showing a cell unit;

FIG. 5 is a view showing a layout as a first comparative example;

FIG. 6 is a view showing a layout as a second comparative example;

FIG. 7 is a view showing a layout as a first embodiment;

FIG. 8 is a view showing a layout as a second embodiment;

FIG. 9 is a view showing a layout as the second embodiment;

FIG. 10 is a view showing a layout as a third embodiment;

FIG. 11 is a view showing a layout as a fourth embodiment;

FIG. 12 is a view showing a layout as the fourth embodiment;

FIG. 13 is a view showing a device structure as a fifth embodiment;

FIG. 14 is a cross sectional view along XIV-XIV line of FIG. 13;

FIG. 15 is a view showing a layout as a sixth embodiment;

FIG. 16 is a view showing a layout as the sixth embodiment;

FIG. 17 is a view showing a layout as the sixth embodiment; and

FIG. 18 is a view showing a layout as the sixth embodiment.

### DETAILED DESCRIPTION OF THE INVENTION

A nonvolatile semiconductor memory of an aspect of the present invention will be described below in detail with reference to the accompanying drawing.

### 1. Outline

The subject of an example of the present invention is a nonvolatile semiconductor memory in which a memory cell array is composed of a plurality of blocks. The respective blocks have block addresses different from one another, and a row address of the word line within one block is the same as a row address of the word line within another block.

In such a nonvolatile semiconductor memory, there are provided two or more signal lines for supplying the transfer voltage to a plurality of word lines disposed in different blocks and having the same row address.

There is adopted a constitution in which, specifically, a plurality of word lines having the same row address are not connected to common one signal line via the respective transfer transistors, but first and second word lines having the same row address are connected to a first signal line and a second signal line, respectively.

According to such constitution, even if a pitch in the column direction of the transfer transistor becomes larger than a pitch of the block (NAND string), a layout of the conductive lines within the word line driver does not become complicated, and therefore it is possible to avoid increase of the parasitic capacitance.

### 2. Embodiments

Embodiments will be described with the NAND type flash memory as an example.

### (1) Overall View

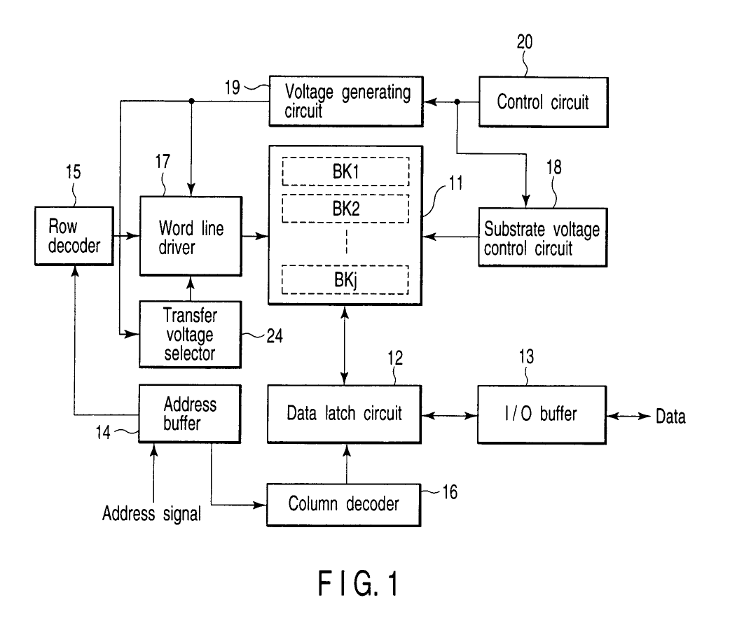

FIG. 1 shows an overall view of the NAND type flash memory.

A memory cell array 11 is composed of a plurality of blocks BK1, BK2, . . . BLj. Each of the plurality of blocks BK1, BK2, . . . BLj has a plurality of cell units, and each of the plurality of cell units is composed of a NAND string composed of a plurality of memory cells connected in series, and two select gate transistors connected to both ends of the NAND string one by one.

A data latch circuit 12 has a function to latch data temporarily at the time of read/write, and is composed of, for example, a flip-flop circuit. An I/O (input/output) buffer 13 functions as an interface circuit of the data, and an address buffer 14 functions as an interface circuit of an address signal.

The address signals include a block address signal, a row address signal and a column address signal.

A row decoder 15 selects one of the plurality of blocks BK1, BK2, . . . BLj based on the block address signal, and then selects one of the plurality of word lines within the selected block based on the row address signal. A word line driver 17 drives the plurality of word lines within the selected block.

A column decoder 16 selects one of a plurality of bit lines based on the column address signal.

A substrate voltage control circuit 18 controls voltage of a semiconductor substrate. Specifically, a double well region composed of an n-type well region and a p-type well region is formed within a p-type semiconductor substrate. When the memory cell is formed within the p-type well region, the substrate voltage control circuit 18 controls the voltage of the p-type well region in accordance with an operation mode.

For example, the substrate voltage control circuit 18, at the time of read/write, sets the p-type well region to 0V, while at the time of erase, sets the p-type well region to voltage of 15V or more and 40V or less.

A voltage generating circuit 19 generates voltage for controlling the word line driver 17, and further generates the transfer voltage supplied to the plurality of word lines within the selected block.

A transfer voltage selector 24 selects values of the transfer voltage supplied to each of the plurality of word lines within the selected block based on information such as an operation mode and a position of the selected word line.

For example, at the time of write, a write voltage as the transfer voltage is supplied to the selected word line within the selected block, while a pass voltage lower than the write voltage as the transfer voltage is supplied to a non-selected word line within the selected block.

Further, at the time of read, a read voltage as the transfer voltage is supplied to the selected word line within the selected block, while voltage higher than the read voltage as the transfer voltage is supplied to a non-selected word line within the selected block.

A control circuit 20 controls, for example, operations of the substrate voltage control circuit 18 and the voltage generating circuit 19.

### (2) Memory cell array and word line driver

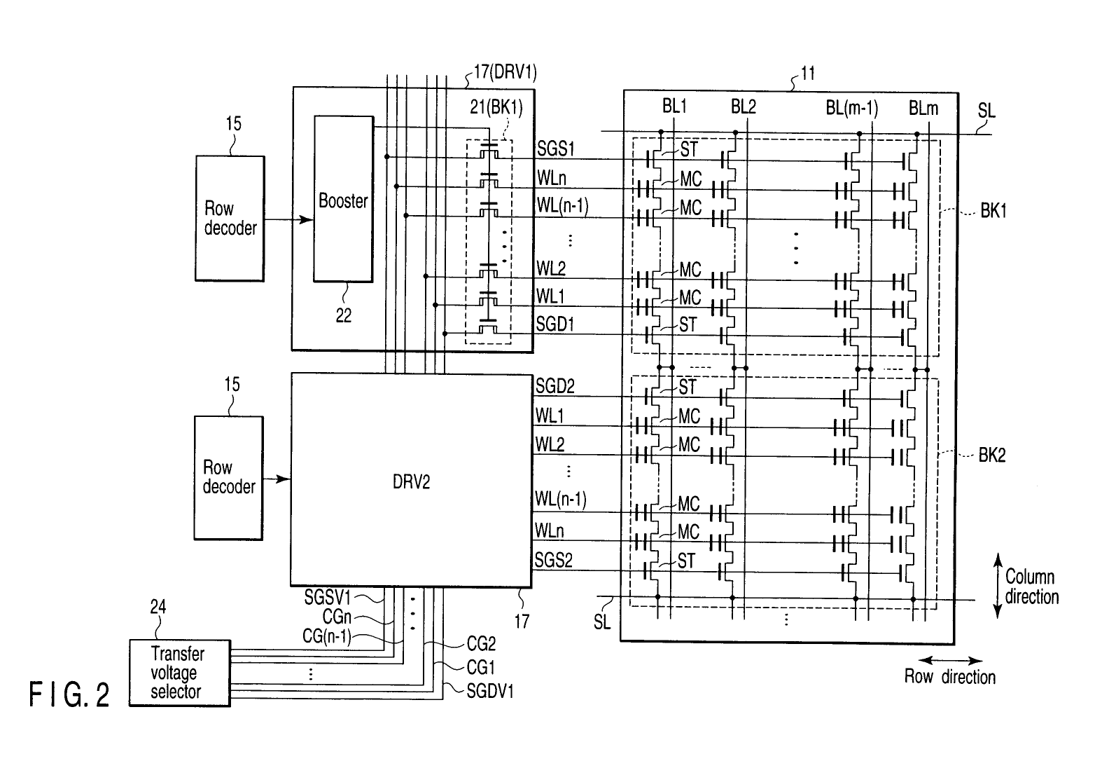

FIG. 2 shows the memory cell array and the word line driver in the NAND type flash memory.

The memory cell array 11 is composed of a plurality of blocks BK1, BK2 . . . arranged in the column direction.

The respective blocks have a plurality of cell units arranged in the row direction. Each of the plurality of cell units is composed of a NAND string composed of a plurality of memory cells MC connected in series, and two select gate transistors ST connected to both ends of the NAND string one by one.

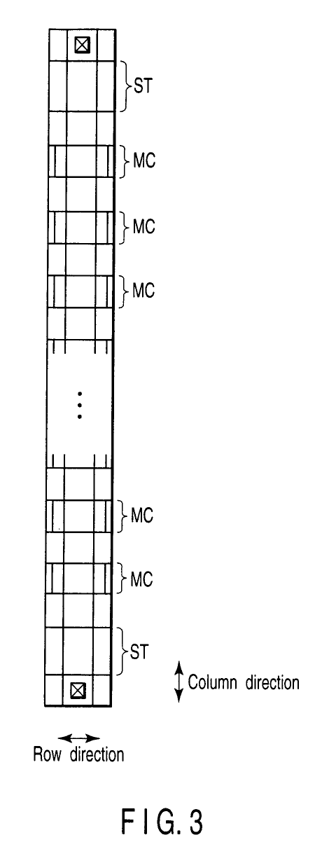

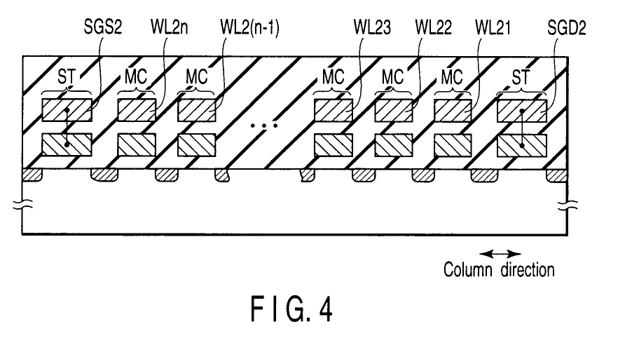

The cell unit has, for example, a layout as shown in FIG. 3. A cross sectional structure in the column direction of the cell unit is, for example, a structure as shown in FIG. 4.

One end of the cell unit is connected to bit lines BL1, BL2, . . . BLm, and the other end thereof is connected to a source line SL.

A plurality of word lines WL1, . . . WLn and a plurality of select gate lines SGS1, SGD1, . . . are arranged on the memory cell array 11.

For example, n (n is plural number) word lines WL1, . . . WLn and two select gate lines SGS1 and SGD1 are arranged within the block BK1. The word lines WL1, . . . WLn and the select gate lines SGS1 and SGD1 extend in the row direction, and each of them is connected to signal lines (control gate line) CG1, . . . CGn and signal lines SGSV1 and SGDV1 via a transfer transistor unit 21 (BK1) within the word line driver 17 (DRV1).

The signal lines CG1, . . . CGn, SGSV1 and SGDV1 extend in the column direction crossing the row direction respectively, and are connected to a transfer voltage selector 24.

A transfer transistor unit 21 (BK1) is composed of a high voltage type MISFET so as to transfer the transfer voltage higher than source voltage Vcc.

A booster 22 within the word line driver 17 (DRV1) receives a decode signal outputted from the row decoder 15. The booster 22 turns the transfer transistor unit 21 (BK1) ON when the block BK1 is selected, while the booster 22 turns the transfer transistor unit 21 (BK1) OFF when the block BK1 is not selected.

### (3) FIRST COMPARATIVE EXAMPLE

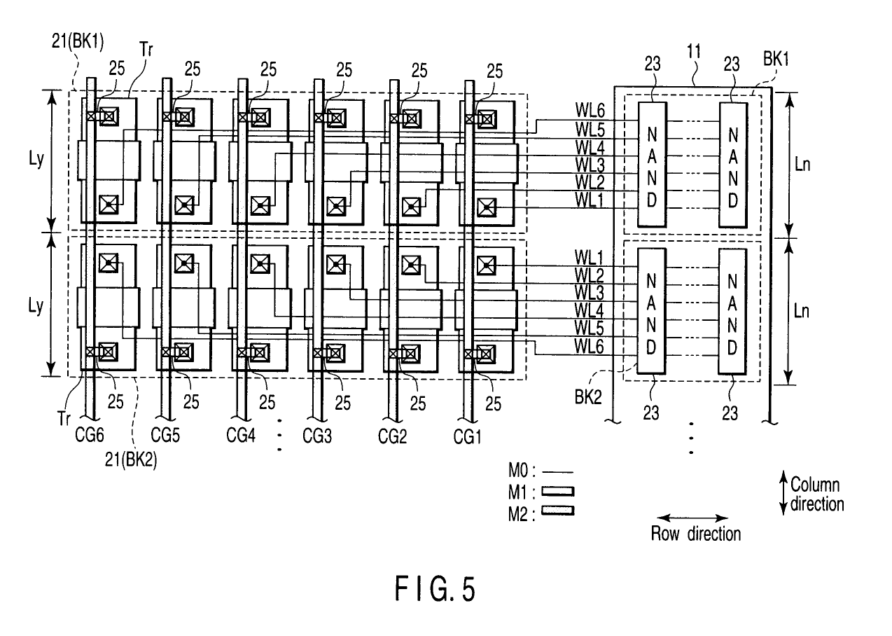

FIG. 5 shows a layout of the transfer transistor within the word line driver as the first comparative example.

A NAND string 23 within the blocks BK1, BK2, . . . is composed of a plurality of memory cells connected in series. In the present example, the NAND string 23 is assumed to be constituted from six memory cells. In this case, six word lines WL1, WL2, . . . WL6 are arranged within one block.

The word lines WL1, WL2, . . . WL6 are formed, for example, on a wiring layer M0 on the semiconductor substrate.

The transfer transistor units 21 (BK1), 21 (BK2), . . . corresponding to the blocks BK1, BK2, . . . are arranged at one end side of the memory cell array 11. Further, the transfer transistor units 21 (BK1), 21 (BK2), . . . are composed of MISFETs, and all of them are oriented in the same direction. That is, a transfer transistor Tr is arranged with the layout in which a transfer channel direction (channel length direction) of the transfer voltage is the column direction.

Signal lines CG1, CG2, . . . CG6 are arranged on the transfer transistor units 21 (BK1), 21 (BK2), Further, the signal lines CG1, CG2, . . . CG6 and the transfer transistor Tr are connected to one another by the conductive line 25.

The conductive line 25 is, for example, formed on the wiring layer M1 on the wiring layer M0, and the signal lines CG1, CG2, . . . CG6 are, for example, formed on the wiring layer M2 on the wiring layer M1.

Here, the size Ly in the column direction of the transfer transistor Tr is the same as or smaller than the size Ln in the column direction of the NAND string 23.

For this reason, in the present example, six transfer transistors Tr corresponding to six word lines WL1, WL2, . . . WL6 within one block are simply laid out in one line within width Ln in the column direction of the NAND string 23.

In this case, the signal lines CG1, CG2, . . . CG6 can be arranged just above the six transfer transistors Tr within the transfer transistor units 21 (BK1), 21 (BK2), . . . . In other words, it is possible to adopt the layout in which one of the signal lines CG1, CG2, . . . CG6 is arranged just above one transfer transistor Tr within the transfer transistor units 21 (BK1), 21 (BK2),

Therefore, the conductive line 25 for connecting the signal lines CG1, CG2, . . . CG6 and the transfer transistor Tr has a short and simple layout.

### (4) SECOND COMPARATIVE EXAMPLE

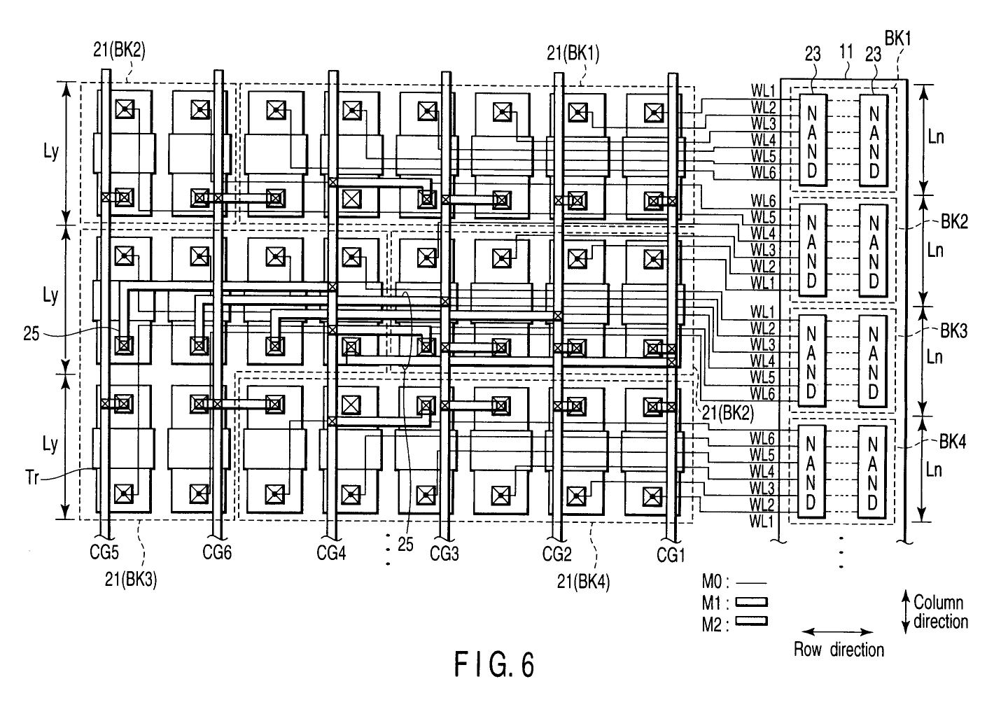

FIG. 6 shows a layout of the transfer transistor within the word line driver as the second comparative example.

FIG. 6 is different from FIG. 5 in that the size Ly in the column direction of the transfer transistor Tr is larger than the size Ln in the column direction of the NAND string 23.

Development of shrinkage of the transfer transistor accompanied with the advanced micro-fabrication technology is slower than development of shrinkage of the memory cell, so that, in most of the existing NAND type flash memories, the size Ly in the column direction of the transfer transistor Tr becomes larger than the size Ln in the column direction of the NAND string 23.

For this reason, it is not possible to simply lay out the six transfer transistors Tr corresponding to the six word lines WL1, WL2, . . . WL6 within one block in one line within the width Ln in the column direction of the NAND string 23.

Consequently, in the present example, the size Ly in the column direction of the transfer transistor Tr multiplied by 3 is the same as or smaller than the size Ln in the column direction of the NAND string 23 multiplied by 4.

In this case, the array of the transfer transistor Tr becomes 3 (column direction)×8 (row direction) with respect to four NAND strings 23 in the column direction. Further, the layout of the transfer transistor units 21 (BK1), 21 (BK2), . . . corresponding to the blocks BK1, BK2, . . . becomes irregular.

As a result, when the number of the signal lines CG1, CG2, . . . CG6 remains in six, physically, it is not possible to arrange one of the signal lines CG1, CG2, . . . CG6 just above the whole transfer transistors Tr.

For this reason, the conductive line 25 for connecting the signal lines CG1, CG2, . . . CG6 to the transfer transistor Tr has a long and complicated layout.

Further, since the conductive line 25 exists in a lower layer (semiconductor substrate side) than the signal lines CG1, CG2, . . . CG6, that the conductive line 25 becomes long means that the parasitic capacitance generated therein increases.

Since increase of the parasitic capacitance lowers signal speed, it is not preferable for improvement of write/read speed that the conductive line 25 becomes long and complicated.

### (5) First Embodiment

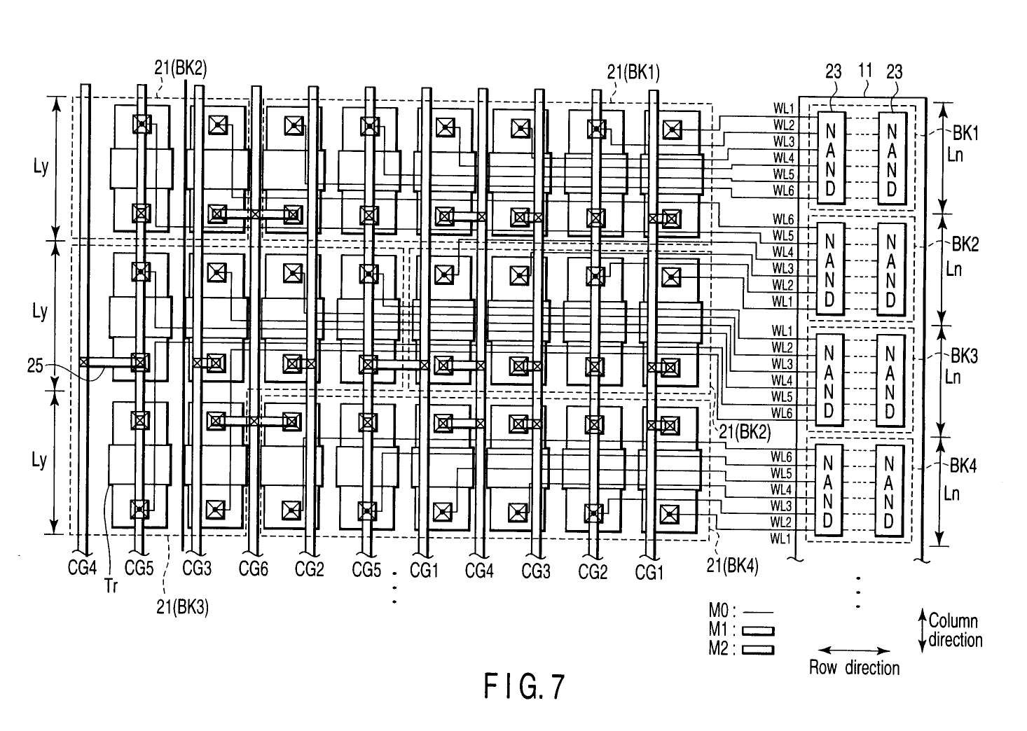

FIG. 7 shows a layout of the transfer transistor within the word line driver as the first embodiment.

Characteristics of the first embodiment are that the number of the signal lines extending in the column direction and leading the transfer voltage to the word lines is more than those of the first and second comparative examples.

Specifically, two or more signal lines are provided to a plurality of word lines having the same row address. However, it is acceptable as long as this condition is satisfied for at least one word line within the block. That is, when the number of the word lines within the block is six, there must be seven or more signal lines in the first embodiment.

As in the first and second comparative examples, it is assumed that the NAND string 23 within the blocks BK1, BK2, . . . is composed of six memory cells. Therefore, six word lines WL1, WL2, . . . WL6 are arranged within one block.

The word lines WL1, WL2, . . . WL6 are formed on, for example, the wiring layer M0 on the semiconductor substrate.

The transfer transistor units 21 (BK1), 21 (BK2), . . . are arranged at one end side of the memory cell array 11 corresponding to the blocks BK1, BK2, . . . . Further, the transfer transistor units 21 (BK1), 21 (BK2), . . . are composed of the MISFET.

Here, all orientation of the transfer transistor Tr, like the first and second comparative examples, is caused to be the same, and the transfer channel direction (channel length direction) of the transfer voltage is caused to be the column direction.

The signal lines CG1, CG2, . . . CG6, CG1′, CG2′, . . . CG5′ are arranged on the transfer transistor units 21 (BK1), 21 (BK2), . . . . The number of the signal line corresponding to the word lines WL1, . . . WL5 is two each, and the number of the signal line corresponding to the word line WL6 is one.

Therefore, total of the signal lines CG1, CG2, . . . CG6, CG1′, CG2′, . . . CG5′ are eleven.

Further, the signal lines CG1, CG2, . . . CG6, CG1′, CG2′, . . . CG5′ and the transfer transistor Tr are connected to one another by the conductive line 25.

The conductive line 25 is formed on, for example, the wiring layer M1 on the wiring layer M0, while the signal lines CG1, CG2, . . . CG6, CG1′, CG2′, . . . CG5′ are formed on, for example, the wiring layer M2 on the wiring layer M1.

Here, like the second comparative example, the array of the transfer transistor Tr becomes 3 (column direction)×8 (row direction) with respect to four NAND strings 23 in the column direction. In this case, like the second comparative example, the layout of the transfer transistor units 21 (BK1), 21 (BK2), . . . corresponding to the blocks BK1, BK2, . . . becomes irregular.

However, in the first embodiment, there are provided two signal lines each corresponding to the word lines WL1, . . . WL5.

As a result, it is possible to arrange the signal lines adjacent to and connected to the respective transfer transistors Tr, and therefore the conductive line 25 for connecting the signal lines CG1, CG2, . . . CG6, CG1′, CG2′, . . . CG5′ and the transfer transistor Tr has a short and simple layout.

Therefore, it is possible to achieve improvement in the write/read speed, without increasing the parasitic capacitance generated in the conductive line 25.

Meanwhile, with respect to the signal lines CG1, CG2, . . . CG5, and the signal lines CG1′, CG2′, . . . CG5′, the transfer voltage may be supplied to the both at the same time, or may be supplied to only one of the both.

### (6) Second Embodiment

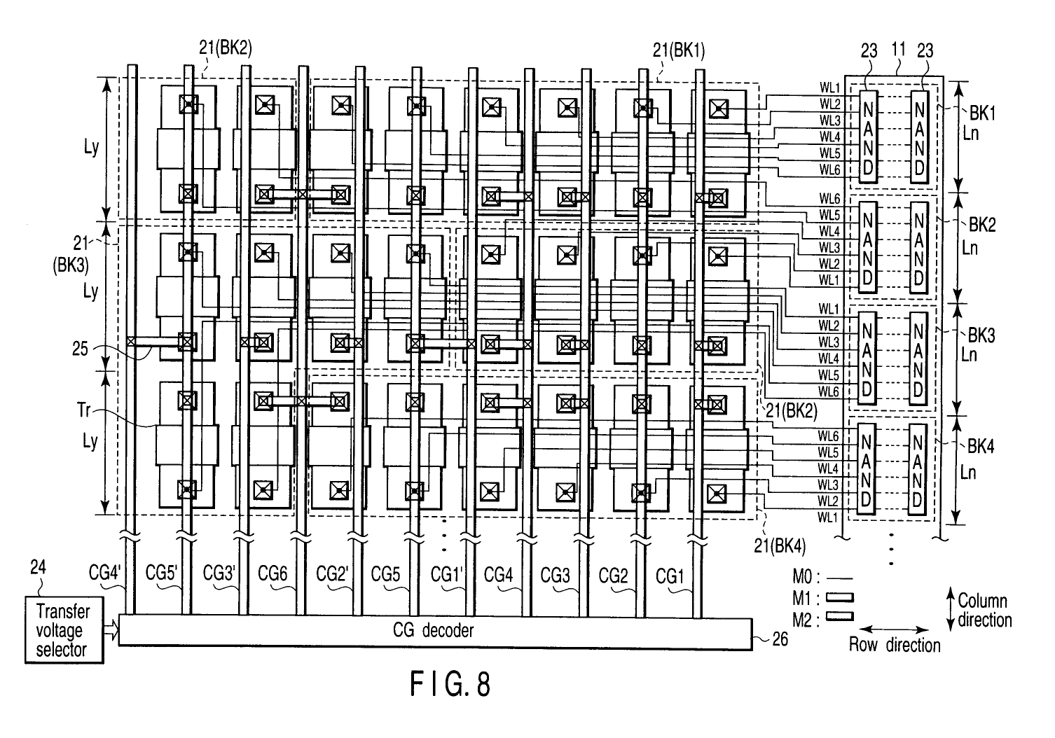

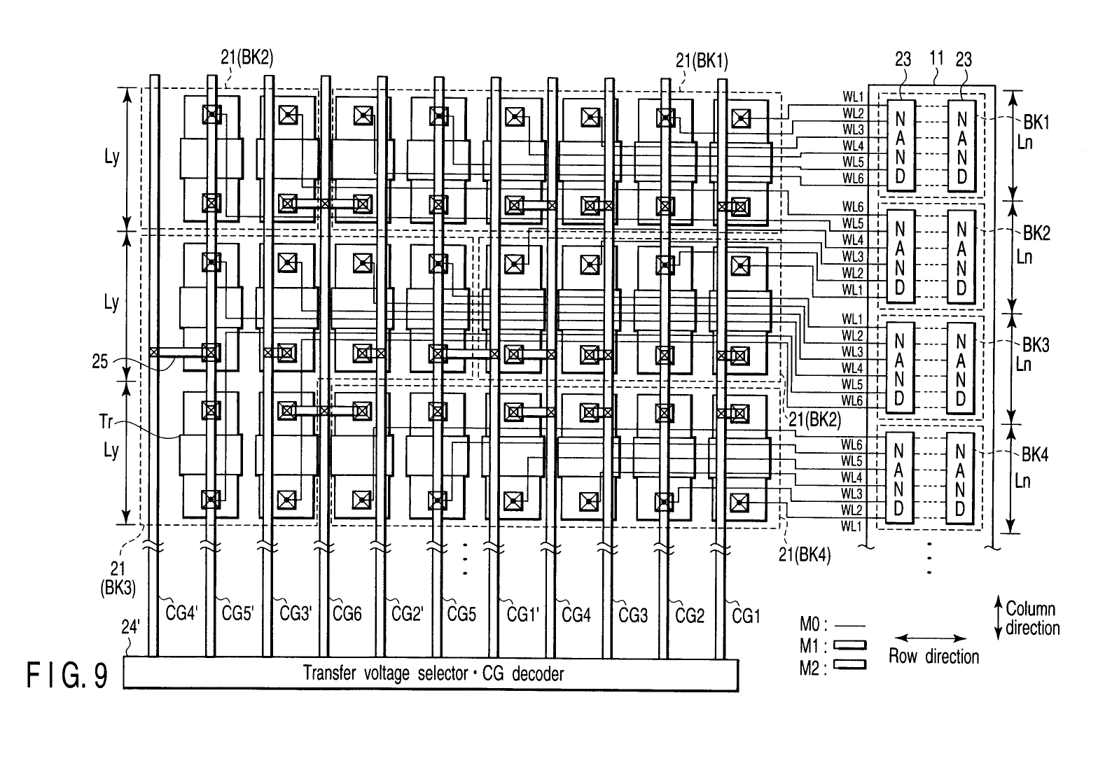

FIGS. 8 and 9 show layouts of the transfer transistor within the word line driver as the second embodiment.

Since the second embodiment is an application example of the first embodiment, the second embodiment includes all the characteristics of the first embodiment. Therefore, here, only different portion from the first embodiment will be described.

The second embodiment further adds a CG (control gate line) decoder 26 to a circuit of the first embodiment.

That is, in the case of FIG. 8, the CG decoder 26 is connected between the transfer voltage selector 24 and the signal lines CG1, CG2, . . . CG6, CG1′, CG2′, . . . CG5′. Further, in the case of FIG. 9, the CG decoder constitutes a transfer voltage selector/CG decoder 24′ integrally with the transfer voltage selector.

The CG decoders 24′, 26 have a function to supply the transfer voltage only to the signal line connected to the word line within the selected block.

For example, when the block BK1 is selected, the transfer voltage transferred to the word lines WL1, WL2, . . . WL6 within the block BK1 is selectively outputted to the signal lines CG1, CG2, . . . CG6 from the CG decoders 24′, 26.

Further, when the block BK2 is selected, the transfer voltage transferred to the word lines WL1, WL2, . . . WL6 within the block BK2 is selectively outputted to the signal lines CG1′, CG2′, . . . CG5′, CG6 from the CG decoders 24′, 26.

Thus, it is possible to suppress increase of the parasitic capacitance caused by increase in the number of the signal line, in such a way that the transfer voltage is not outputted to the signal line connected to the non-selected blocks.

### (7) Third Embodiment

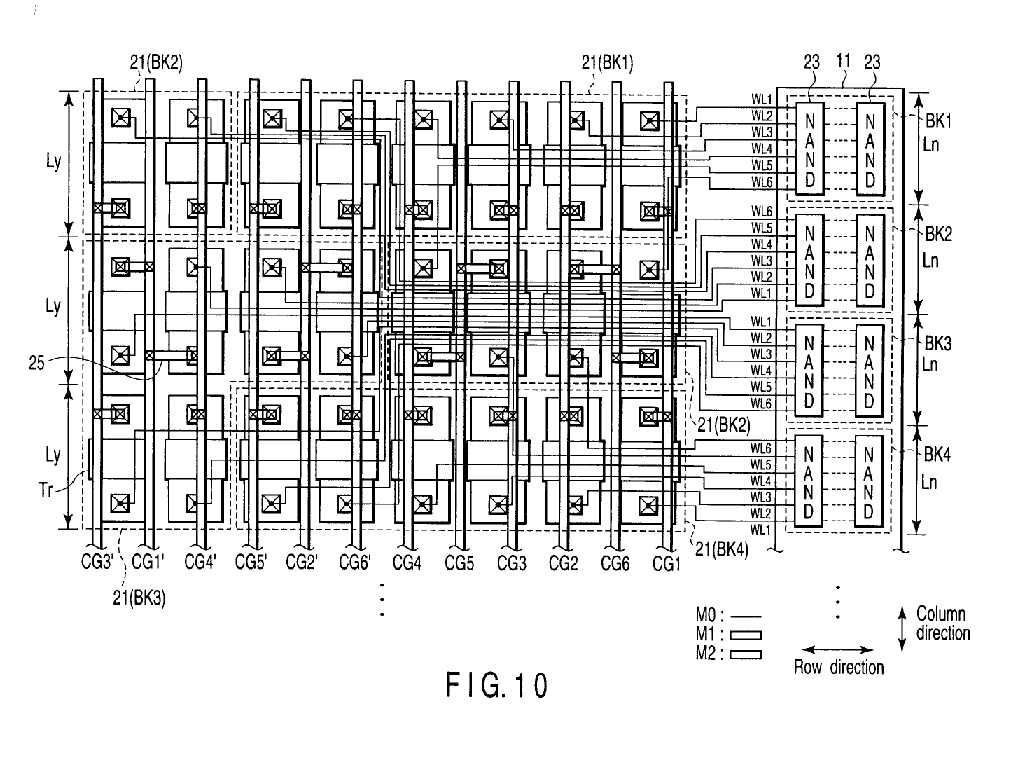

FIG. 10 shows a layout of the transfer transistor within the word line driver as the third embodiment.

Since the third embodiment is a modified example of the first embodiment, description with respect to the same part as the first embodiment will be omitted.

The third embodiment is different from the first embodiment in the number of the signal line.

In the third embodiment, since there exist two signal lines each corresponding to the word lines WL1, WL2, . . . WL6, total of the signal lines CG1, CG2, . . . CG6, CG1′, CG2′, . . . CG6′ are twelve.

Thus, it is possible to suppress variations in characteristics relating to the word line in such a way that the number of the signal lines is made m (m is natural number of 2 or more) times the number of the word line within one block.

Further, the conductive line 25 for connecting the signal lines CG1, CG2, . . . CG6, CG1′, CG2′, . . . CG6′ to the transfer transistor Tr has a short and simple layout.

### (8) Fourth Embodiment

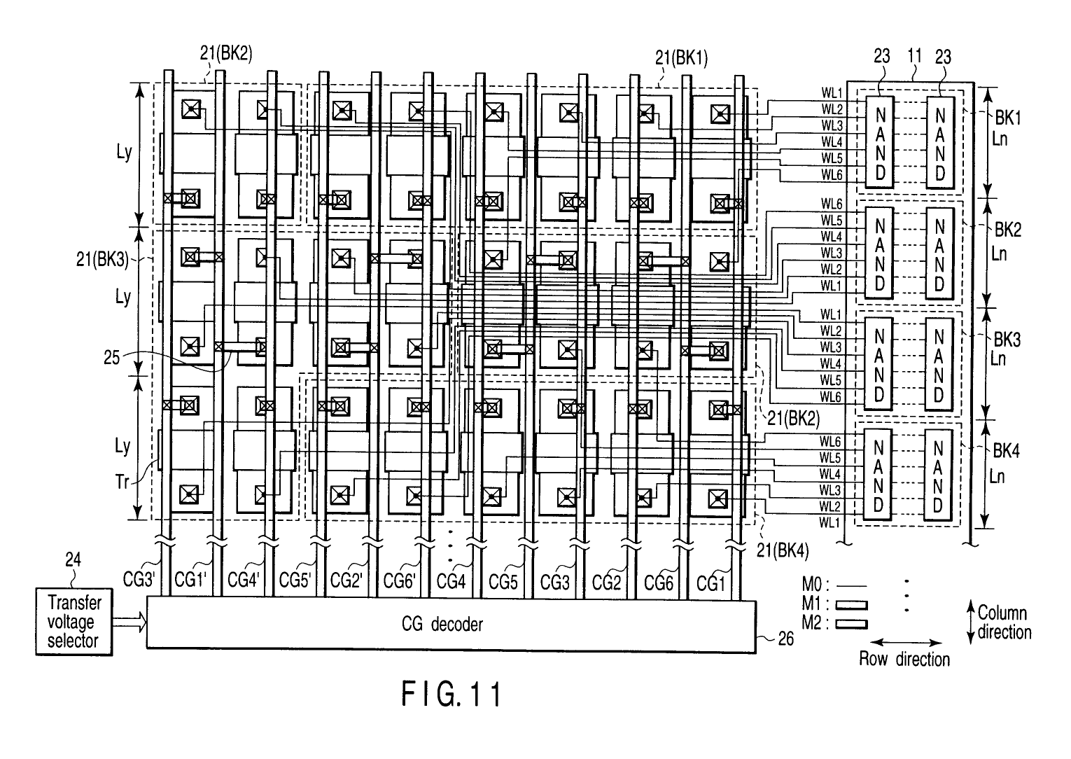

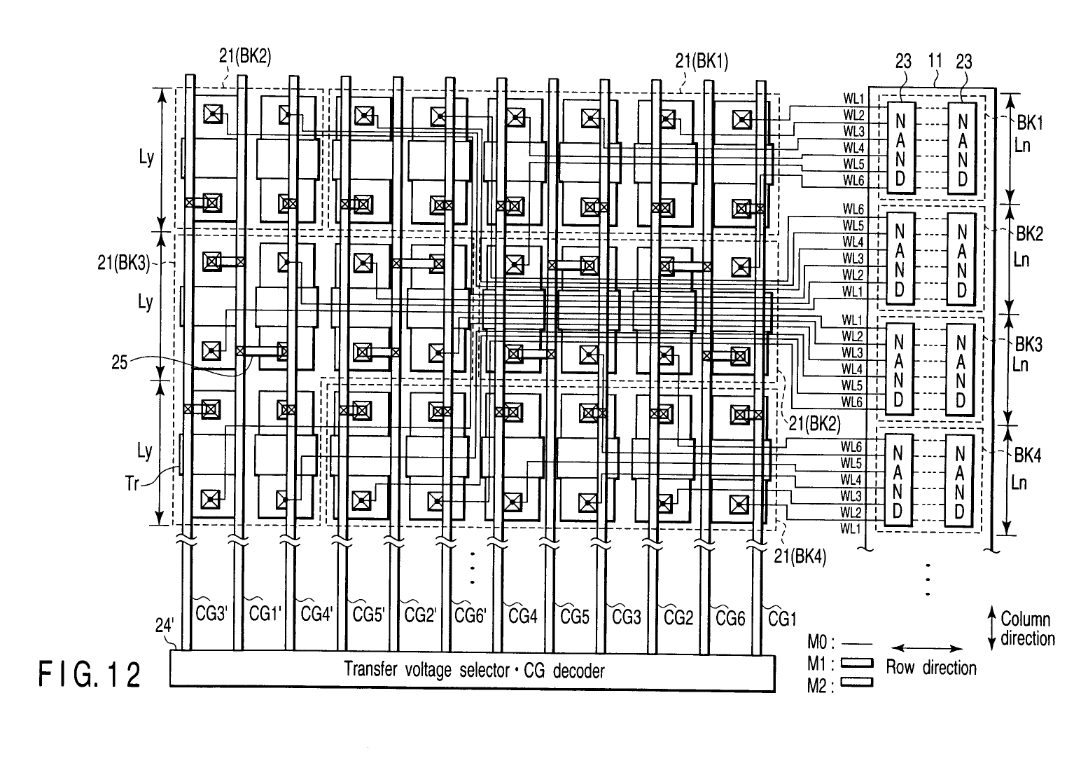

FIGS. 11 and 12 show layouts of the transfer transistor within the word line driver as the fourth embodiment.

Since the fourth embodiment is an application example of the third embodiment, the fourth embodiment includes all the characteristics of the third embodiment. Therefore, here, only different portion from the third embodiment will be described.

The fourth embodiment further adds a CG decoder 26 to the circuit of the third embodiment.

That is, in the case of FIG. 11, the CG decoder 26 is connected between the transfer voltage selector 24 and the signal lines CG1, CG2, . . . CG6, CG1′, CG2′, . . . CG6′. Further, in the case of FIG. 12, the CG decoder constitutes the transfer voltage selector/CG decoder 24′ integrally with the transfer voltage selector.

The CG decoders 24′, 26 have a function to supply the transfer voltage only to the signal lines connected to the word lines within the selected block.

For example, when the block BK1 is selected, the transfer voltage transferred to the word lines WL1, WL2, . . . WL6 within the block BK1 is selectively outputted to the signal lines CG1, CG2, . . . CG6 from the CG decoders 24′, 26.

Further, when the block BK2 is selected, the transfer voltage transferred to the word lines WL1, WL2, . . . WL6 within the block BK2 is selectively outputted to the signal lines CG1′, CG2′, . . . CG6′ from the CG decoders 24′, 26.

Thus, it is possible to suppress increase of the parasitic capacitance caused by increase in the number of the signal line, in such a way that the transfer voltage is not outputted to the signal line connected to the non-selected blocks.

### (9) Fifth Embodiment

The fifth embodiment relates to a device structure.

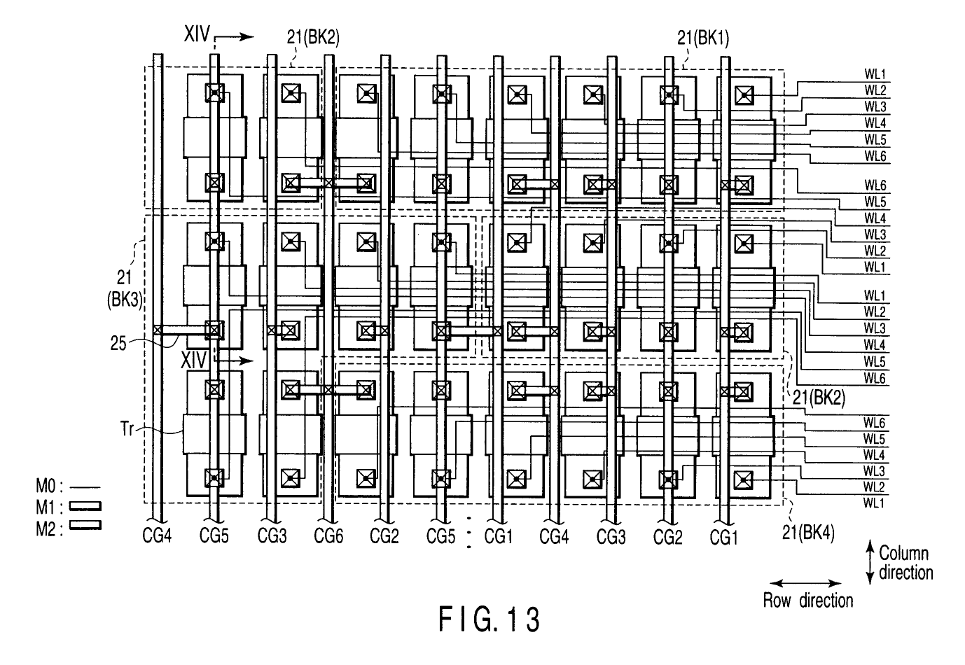

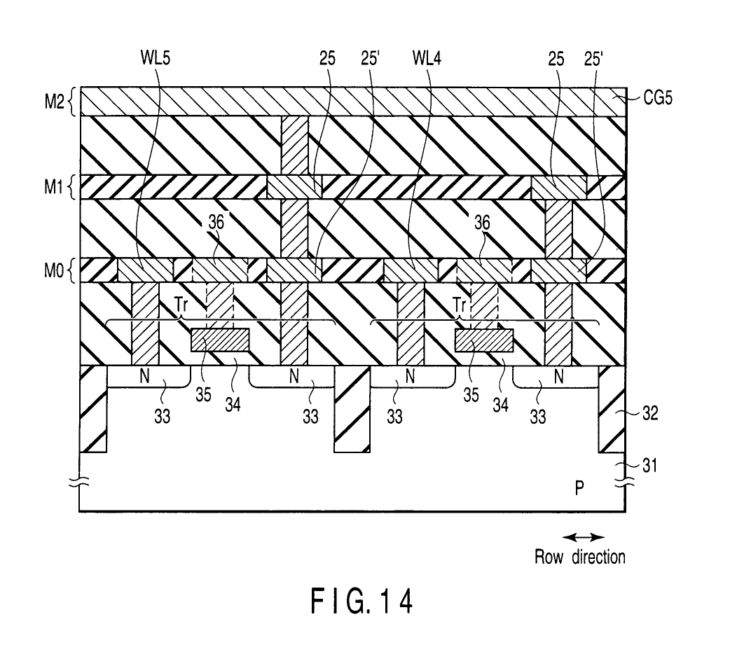

FIGS. 13 and 14 show examples of the device structure of the transfer transistor. FIG. 14 is a cross sectional view along XIV-XIV line of FIG. 13.

An element isolation insulating layer 32 with an STI (shallow trench isolation) structure is formed in a semiconductor substrate 31. The MISFET as the transfer transistor Tr is formed on the semiconductor substrate (element region) 31 surrounded by the element isolation insulating layer 32.

The transfer transistor Tr is composed of a source/drain diffusion layer 33, a gate insulating layer 34 on the channel between the source/drain diffusion layers 33, and a gate electrode 35 on the gate insulating layer 34.

A gate conductive line 36 is connected to the gate electrode 35. The gate conductive line 36 is made of metal and formed in the wiring layer M0.

Also the word lines WL1, WL2, . . . WL6 are made of metal and formed within the wiring layer M0. Further, the word lines WL1, WL2, . . . WL6 are constituted from conductive polysilicon (control gate electrode of memory cell) within the memory cell array.

The metal and the conductive polysilicon as the word lines WL1, WL2, . . . WL6 are coupled to one another by a contact plug at an edge part of the memory cell array.

The conductive lines 25′, 25 formed within the wiring layers M0, M1 electrically connect the transfer transistor Tr with the signal lines CG1, CG2, . . . CG6, CG1′, CG2′, CG5′. The signal lines CG1, CG2, CG6, CG1′, CG2′, . . . CG5′ are formed on the wiring layer M2.

Both the conductive lines 25′, 25 and the signal lines CG1, CG2, . . . CG6, CG1′, CG2′, . . . CG5′ are made of metal.

### (10) Sixth Embodiment

The sixth embodiment relates to positional relationship between the memory cell array and the word line driver.

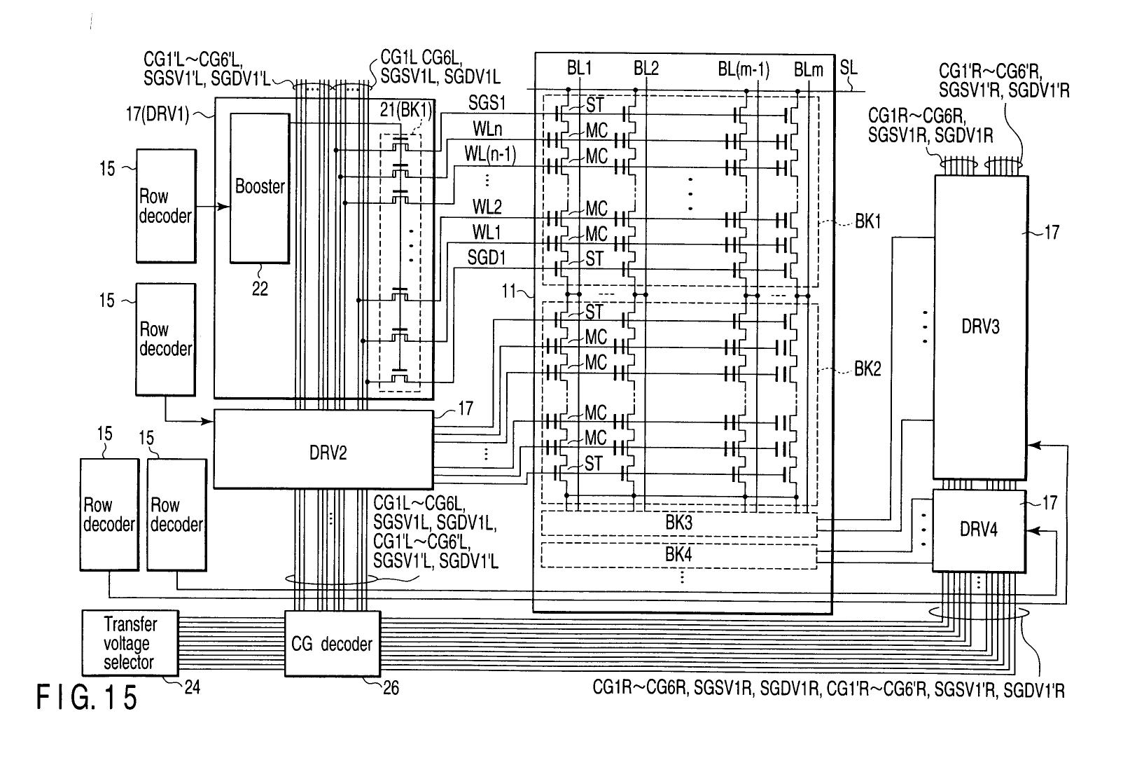

FIGS. 15 to 18 show the memory cell array and the word line driver in the NAND type flash memory.

Characteristics of the sixth embodiment are that the word line drivers 17 (DRV1), 17 (DRV2), . . . each is arranged at both ends of the memory cell array 11.

The word line driver 17 (DRV1) drives the word lines WL1, WL2, . . . WLn within the block BK1. Similarly, the word line drivers 17 (DRV2), 17 (DRV3), 17 (DRV4), . . . drive the word lines within the blocks BK2, BK3, BK4,

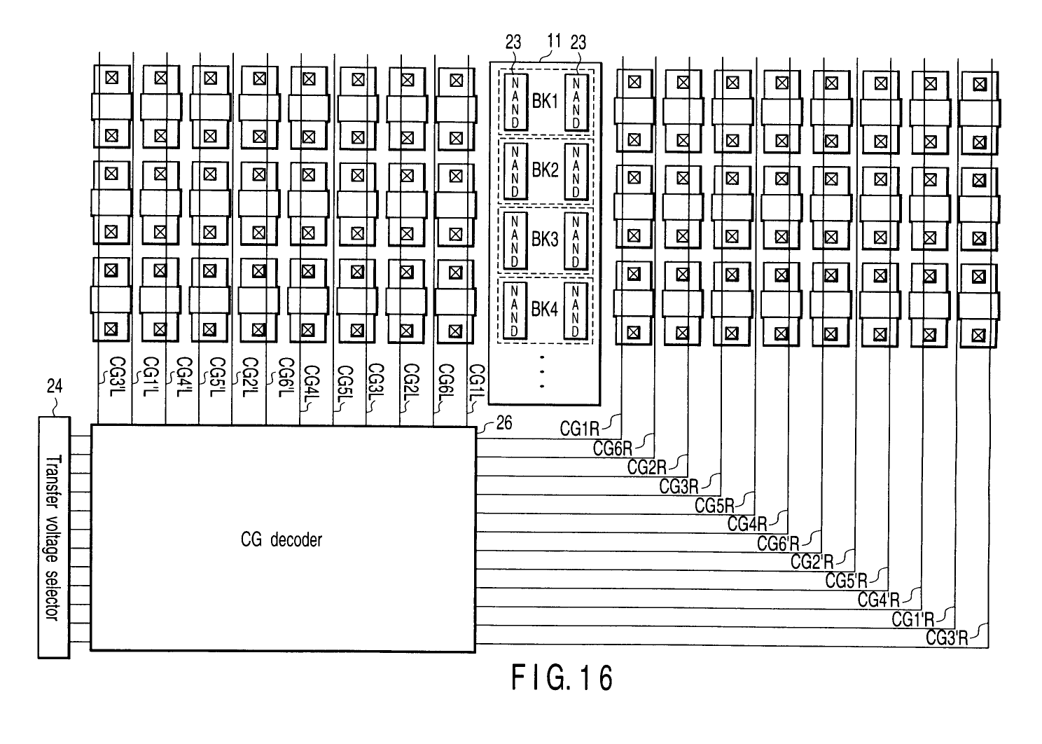

Here, in FIGS. 15 and 16, the CG decoder 26 is connected between the transfer voltage selector 24 and signal lines CG1L, CG2L, . . . CG6L, CG1′L, CG2′L, . . . CG6′L, CG1R, CG2R, . . . CG6R, CG1′R, CG2′R, . . . CG6′R.

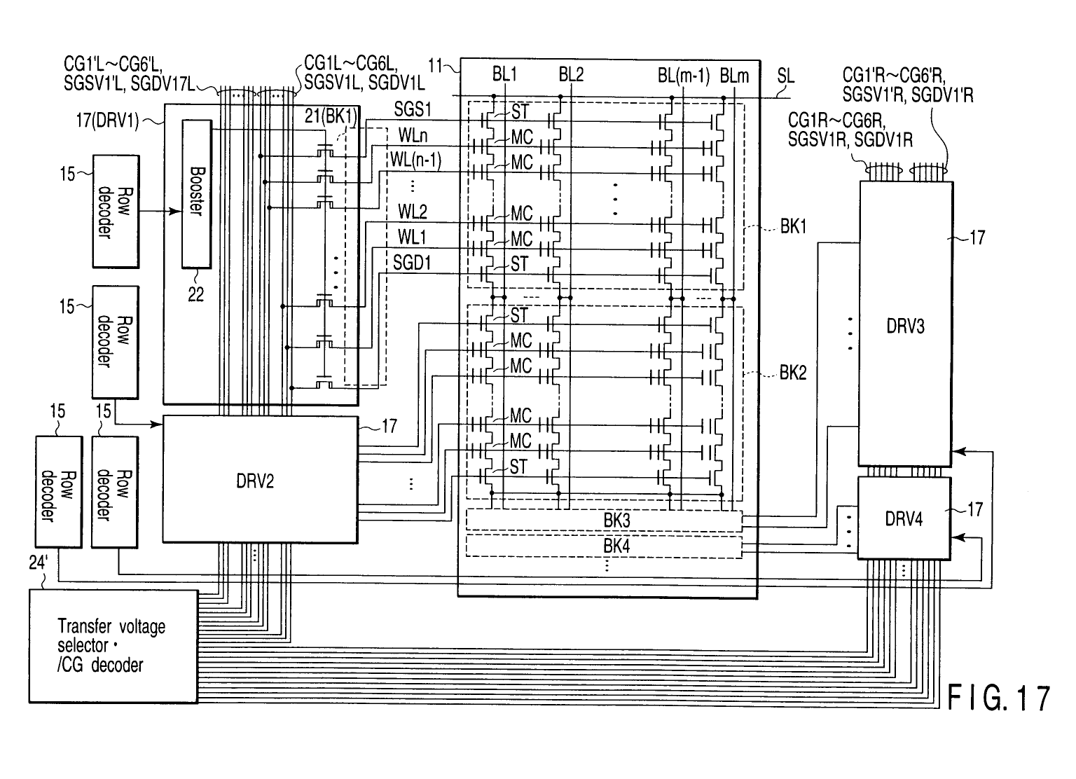

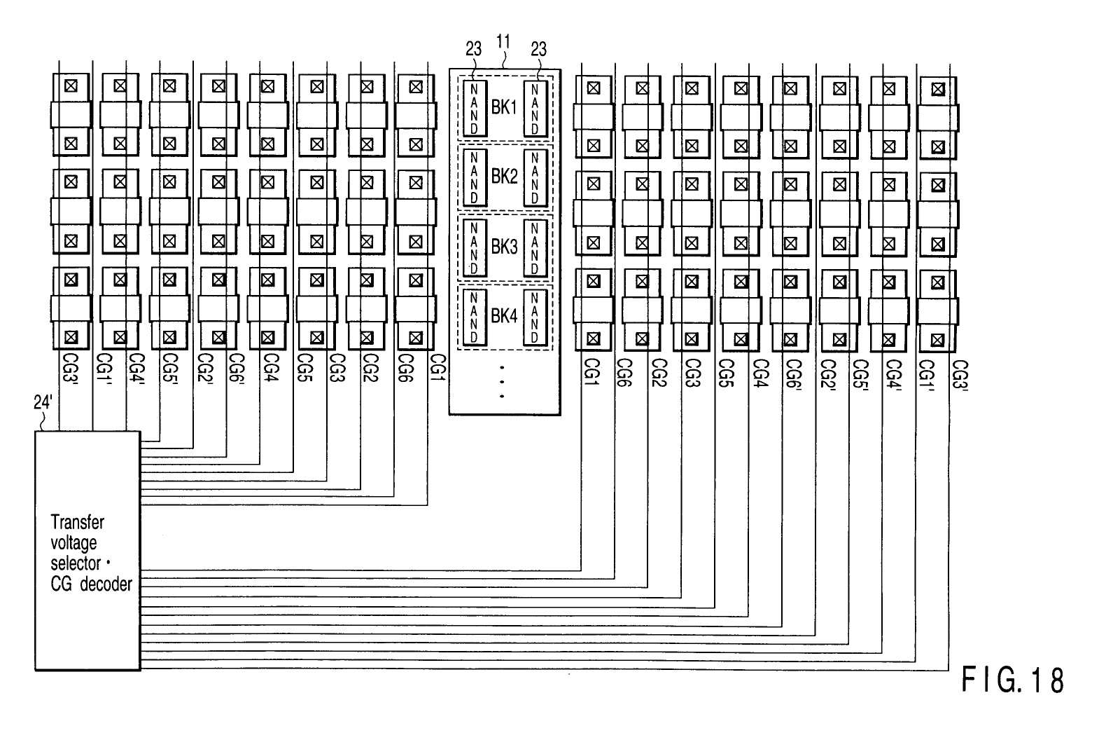

Further, in the case of FIGS. 17 and 18, the CG decoder constitutes a transfer voltage selector/CG decoder 24′ integrally with the transfer voltage selector.

The CG decoders 24′, 26 supply the transfer voltage only to the signal line connected to the word line within the selected block.

For example, when the block BK1 is selected, the transfer voltage transferred to the word lines WL11, WL12, . . . WL1n within the block BK1 is selectively outputted to the signal lines CG1L, CG2L, . . . CG6L at left side of the memory cell array 11 from the CG decoders 24′, 26.

When the block BK2 is selected, the transfer voltage transferred to the word lines within the block BK2 is selectively outputted to the signal lines CG1′L, CG2′L, . . . CG6′L at left side of the memory cell array 11 from the CG decoders 24′, 26.

When the block BK3 is selected, the transfer voltage transferred to the word lines within the block BK3 is selectively outputted to the signal lines CG1R, CG2R, . . . CG6R at right side of the memory cell array 11 from the CG decoders 24′, 26.

When the block BK4 is selected, the transfer voltage transferred to the word lines within the block BK4 is selectively outputted to the signal lines CG1′R, CG2′R, . . . CG6′R at right side of the memory cell array 11 from the CG decoders 24′, 26.

According to such constitution, since the word line drivers 17 (DRV1), 17 (DRV2), . . . each is arranged at both ends of the memory cell array 11, as compared with FIG. 2, room can be made in the layout of the transfer transistor units 21 (BK1),

### (11) Others

The examples of the present invention are not limited by the number of the memory cell constituting the NAND string. Also, the orientation of the MISFET within the transfer transistor unit is not limited to that in the above described embodiments.

For example, the transfer transistor may also have the transfer channel direction (channel length direction) of the transfer voltage in row direction. Further, the transfer transistor unit may be constituted in such a way that the MISFET having the transfer channel of the transfer voltage in the column direction is combined with the MISFET having the transfer channel of the transfer voltage in the row direction.

Further, wiring layer in which the word lines are formed, wiring layer in which the signal lines are formed, and wiring layer in which the conductive lines are different from each other. However, it is not limited to this.

For example, a whole or part of the wiring layer in which the word lines are formed and a whole or part of the wiring layer in which the conductive lines for connecting the word lines and the signal lines are formed may be formed in the same wiring layer.

Although the above embodiments have described the NAND type flash memory, the examples of the present invention are applicable to whole types of the nonvolatile semiconductor memory in which the memory cell array is composed of a plurality of blocks.

### 3. Conclusion

According to the examples of the present invention, it is possible to suppress generation of the parasitic capacitance by simplifying the layout of the conductive line within the word line driver.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory comprising:
first and second word lines extending in a first direction and having the same row address;
a first block including the first word line and having a first block address;
a second block including the second word line and having a second block address;
first and second signal lines extending in a second direction crossing the first direction;
a first transfer transistor connected between the first word line and the first signal line;
a second transfer transistor connected between the second word line and the second signal line; and
a transfer voltage selector to output a transfer voltage to the first and second signal lines.

2. The nonvolatile semiconductor memory according to claim 1, further comprising:
a first conductive line connected between the first signal line and the first transfer transistor; and
a second conductive line connected between the second signal line and the second transfer transistor.

3. The nonvolatile semiconductor memory according to claim 2,
wherein a wiring layer in which the first and second word lines are formed, a wiring layer in which the first and second signal lines are formed, and a wiring layer in which the first and second conductive lines are formed are different from one another.

4. The nonvolatile semiconductor memory according to claim 3, further comprising:
a CG decoder which selectively outputs the transfer voltage to the first signal line when the first block is selected, and selectively outputs the transfer voltage to the second signal line when the second block is selected.

5. The nonvolatile semiconductor memory according to claim 4,
wherein the first and second blocks each have n (n is plural number) word lines.

6. The nonvolatile semiconductor memory according to claim 5, further comprising:
n signal lines corresponding to the n word lines within the first block; and
n signal lines corresponding to the n word lines within the second block.

7. The nonvolatile semiconductor memory according to claim 6,
wherein the CG decoder selectively outputs the transfer voltage to the n signal lines corresponding to the n word lines within the first block when the first block is selected, and selectively outputs the transfer voltage to the n signal lines corresponding to the n word lines within the second block when the second block is selected.

8. The nonvolatile semiconductor memory according to claim 1,
wherein the first and second signal lines are provided to one end of the first and second blocks.

9. The nonvolatile semiconductor memory according to claim 1,
wherein each of the first and second transfer transistors is a MOS transistor whose channel length direction is a direction in which the first and second blocks are arranged.

10. The nonvolatile semiconductor memory according to claim 9,
wherein a size of the MOS transistor in the channel length direction is larger than that of the first and second blocks in the channel length direction.

11. The nonvolatile semiconductor memory according to claim 1, further comprising:
a third word line extending in the first direction and providing in the first block;
a fourth word line extending in the first direction and providing in the second block;
a third signal line extending in the second direction; and
a third transfer transistor connected between the third and fourth word lines and the third signal line,
wherein the third and fourth word lines have the same row address and the transfer voltage selector outputs the transfer voltage to the third signal line.

12. The nonvolatile semiconductor memory according to claim 11, further comprising:
a third conductive line connected between the third and fourth signal lines and the third transfer transistor.

13. The nonvolatile semiconductor memory according to claim 12,
wherein the CG decoder outputs the transfer voltage to the third signal line when the third or fourth block is selected.

14. The nonvolatile semiconductor memory according to claim 11,
wherein the third and fourth signal lines are provided to one end of the first to fourth blocks.

15. The nonvolatile semiconductor memory according to claim 11,
wherein the third transfer transistors is a MOS transistor whose channel length direction is a direction in which the first to fourth blocks are arranged.

16. The nonvolatile semiconductor memory according to claim 1, further comprising:
third and fourth word lines extending in the first direction and having the same row address;
a third block including the third word line and having a third block address;
a fourth block including the fourth word line and having a fourth block address;
third and fourth signal lines extending in the second direction;
a third transfer transistor connected between the third word line and the third signal line; and
a fourth transfer transistor connected between the fourth word line and the fourth signal line,
wherein the transfer voltage selector outputs the transfer voltage to the third and fourth signal lines.

17. The nonvolatile semiconductor memory according to claim 16, further comprising:
a third conductive line connected between the third signal line and the third transfer transistor; and
a fourth conductive line connected between the fourth signal line and the fourth transfer transistor.

18. The nonvolatile semiconductor memory according to claim 17,
wherein the CG decoder outputs the transfer voltage to the third signal line when the third block is selected, and outputs the transfer voltage to the fourth signal line when the fourth block is selected.

19. The nonvolatile semiconductor memory according to claim 16,
wherein the first and second signal lines are provided to one end of the first to fourth blocks, and the third and fourth signal lines are provided to other end of the first to fourth blocks.

20. The nonvolatile semiconductor memory according to claim 16,
wherein each of the third and fourth transfer transistors is a MOS transistor whose channel length direction is a direction in which the first to fourth blocks are arranged.
